(19) United States
(12) Patent Application Publication
(10) Pub. No.: US 2025/0144892 A1
(43) Pub. Date: May 8, 2025

(54) BONDING METHOD AND BONDING APPARATUS

(71) Applicant: Tokyo Electron Limited, Tokyo (JP)

(72) Inventors: Hirokazu UEDA, Osaka City (JP); Kenji SEKIGUCHI, Nirasaki City (JP); Mitsuaki IWASHITA, Nirasaki City (JP)

(21) Appl. No.: 19/010,575

(22) Filed: Jan. 6, 2025

Related U.S. Application Data
(63) Continuation of application No. PCT/JP2023/024636, filed on Jul. 3, 2023.

(30) Foreign Application Priority Data
Jul. 13, 2022 (JP) 2022-112651

(51) Int. Cl. B29C 65/48

(52) U.S. Cl. CPC B29C 65/4855; B29C 65/483

(57) ABSTRACT

A bonding method includes a first operation of preparing a first substrate having a first surface and a second substrate having a second surface, each of the first surface and the second surface having a first region in which an insulating film is exposed and a second region in which a conductive film is exposed, a second operation of applying an ionic liquid to at least one of the first surface of the first substrate or the second surface of the second substrate, and a third operation of bonding the first surface of the first substrate and the second surface of the second substrate with the ionic liquid.

### CROSS-REFERENCE TO RELATED APPLICATIONS

This application is a bypass continuation application of international application No. PCT/JP2023/024636 having an international filing date of Jul. 3, 2023 and designating the United States, the international application being based upon and claiming the benefit of priority from Japanese Patent Application No. 2022-112651, filed on Jul. 13, 2022, the entire contents of which are incorporated herein by reference.

### TECHNICAL FIELD

The present disclosure relates to a bonding method and a bonding apparatus.

### BACKGROUND

There is known a technology for bonding two substrates, each of which having an insulating film and a conductive film formed on a surface thereof (see Patent Documents 1 and 2).

### PRIOR ART DOCUMENTS

### Patent Documents

Patent Document 1: Japanese Laid-Open Patent Publication No. 2008-135515
Patent Document 2: Japanese Laid-Open Patent Publication No. 2017-098463

### SUMMARY

According to one embodiment of the present disclosure, a bonding method includes a first operation of preparing a first substrate having a first surface and a second substrate having a second surface, each of the first surface and the second surface having a first region in which an insulating film is exposed and a second region in which a conductive film is exposed, a second operation of applying an ionic liquid to at least one of the first surface of the first substrate or the second surface of the second substrate, and a third operation of bonding the first surface of the first substrate and the second surface of the second substrate with the ionic liquid.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a flowchart illustrating a bonding method according to an embodiment.

FIG. 2 is a cross-sectional view illustrating the bonding method according to the embodiment.

FIG. 3 is a cross-sectional view illustrating the bonding method according to the embodiment.

FIG. 4 is a cross-sectional view illustrating the bonding method according to the embodiment.

FIG. 5 is a cross-sectional view illustrating the bonding method according to the embodiment.

FIG. 6 is a cross-sectional view illustrating the bonding method according to the embodiment.

FIG. 7 is a cross-sectional view illustrating the bonding method according to the embodiment.

FIG. 8 is a horizontal cross-sectional view illustrating a bonding apparatus according to an embodiment.

FIG. 9 is a vertical cross-sectional view illustrating the bonding apparatus according to the embodiment.

### DETAILED DESCRIPTION

Hereinafter, non-limitative exemplary embodiments of the present disclosure will now be described with reference to the accompanying drawings. In all the accompanying drawings, the same or corresponding members or components will be denoted by the same or corresponding reference numerals, and redundant explanations thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Bonding Between Substrates]

In recent years, along with the miniaturization and three-dimensionalization of VLSI (Very Large-Scale Integration), attention has been paid to a three-dimension (3D) stacking technique in which electronic circuit elements formed on different substrates, which are separately fabricated, are directly bonded to each other to produce a single electronic circuit element. In particular, a hybrid bonding in which an insulating film and a conductive film formed one substrate are simultaneously bonded to an insulating film and a conductive film formed on another substrate, respectively, and the substrates are compressed against each other, is important in further increasing a speed of VLSI and reducing a power consumption of VLSI. The conductive film is, for example, an electrode pad, and is used for inputting and outputting electrical signals.

In the hybrid bonding, a single element may be formed by bonding two substrates having different permissible thermal budgets (e.g., different kinds of substrates such as a Si substrate obtained by vertically three-dimensional stacking a N-channel (Nch) transistor circuit and a P-channel (Pch) transistor circuit of a C-FET (Complementary-Field Effect Transistor) on the Si substrate and a Ge or III—V group of substrate) after forming electronic circuit elements on the substrates. The hybrid bonding eliminates a need for signal communication between low-impedance input/output circuits formed on the different substrates. This dramatically increases the speed of the signal transmission between the electronic circuit elements formed on the substrates.

Hereinafter, a bonding method capable of suppressing surfaces of substrates bonded to each other from being oxidized will be described as an example of the hybrid bonding.

[Bonding Method]

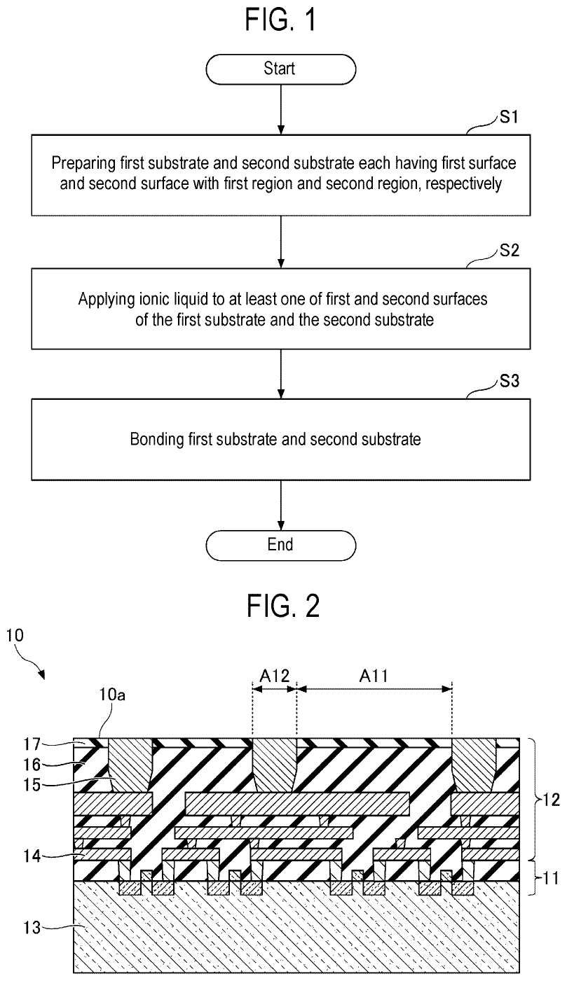

The bonding method according to an embodiment will be described with reference to FIGS. 1 to 7. As illustrated in FIG. 1, the bonding method according to the embodiment includes steps S1 to S3. Steps S1 to S3 are sequentially performed.

In step S1, a first substrate 10 and a second substrate 20 are prepared.

As illustrated in FIG. 2, the first substrate 10 includes a calculation portion 11 and a wiring layer 12.

The calculation portion 11 is formed to include a portion of a base substrate 13. The calculation portion 11 includes semiconductor devices such as transistors. The base substrate 13 is, for example, a semiconductor wafer.

The wiring layer 12 is, for example, a multi-layer wiring. The wiring layer 12 includes a wiring 14, an electrode pad 15, a first insulating film 16, and a second insulating film 17. The wiring 14 is provided in the form of a multi-layer. The wiring 14 is formed of, for example, copper (Cu). The wiring 14 is electrically connected to the calculation portion 11. The electrode pad 15 is provided on the wiring 14 located at the farthest position from the base substrate 13. The electrode pad 15 is electrically connected to the wiring 14. The electrode pad 15 is electrically connected to the calculation portion 11 via the wiring 14. An upper surface of the electrode pad 15 is exposed. The electrode pad 15 is formed of, for example, Cu. The first insulating film 16 is, for example, an interlayer insulating film that fills spaces between the wirings 14. The interlayer insulating film is preferably a low dielectric constant (Low-k) film. The interlayer insulating film is not particularly limited, but may be, for example, a SiO film, a SiN film, a SiOC film, a SiON film, or a SiOCN film. The SiO film means a film containing silicon (Si) and oxygen (O). An atomic ratio of Si to O in the SiO film is not limited to 1:1. The same applies to the SiN film, the SiOC film, the SiON film, and the SiOCN film. The second insulating film 17 is provided on the first insulating film 16. An upper surface of the second insulating film 17 is exposed. The upper surface of the second insulating film 17 is flush with, for example, the upper surface of the electrode pad 15. The second insulating film 17 may be, for example, an insulating film other than the oxide film. In this case, when an ionic liquid is applied to a front surface of the first substrate 10 in step S2, it is possible to suppress the first substrate 10 from being dissolved in the ionic liquid and altered. The second insulating film 17 is, for example, a SiC film.

As an example, the wiring layer 12 may further include a barrier film between the wiring 14 and the first insulating film 16. As an example, the wiring layer 12 may further include a barrier film between the electrode pad 15 and the first insulating film 16. The barrier film suppresses metal from diffusing the wiring 14 and the electrode pad 15 to the first insulating film 16. The barrier film is not particularly limited, but may be, for example, a TaN film or a TiN film. The TaN film means a film containing tantalum (Ta) and nitrogen (N). An atomic ratio of Ta to N in the TaN film is not limited to 1:1. The same applies to the TiN film.

The first substrate 10 has a surface 10a. The surface 10a has a first region A11 in which the second insulating film 17 is exposed and a second region A12 in which the electrode pad 15 is exposed. The second insulating film 17 is an example of an insulating film, and the electrode pad 15 is an example of a conductive film.

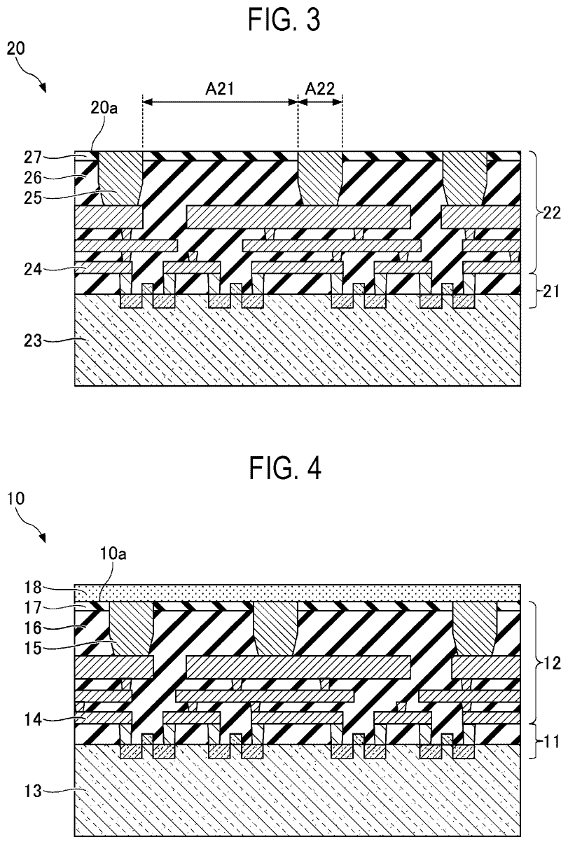

The second substrate 20 is substantially identical in configuration to the first substrate 10. As illustrated in FIG. 3, the second substrate 20 includes a calculation portion 21 and a wiring layer 22.

The calculation portion 21 is formed to include a portion of the base substrate 23.

The wiring layer 22 is, for example, a multi-layer wiring. The wiring layer 22 includes a wiring 24, an electrode pad 25, a first insulating film 26, and a second insulating film 27. The electrode pad 25 is formed of, for example, the same material as the electrode pad 15. In this case, even if the electrode pad 15 and the electrode pad 25 come into contact with each other via an ionic liquid in step S3, bimetallic corrosion (galvanic corrosion) does not occur.

The second substrate 20 has a surface 20a. The surface 20a has a first region A21 in which the second insulating film 27 is exposed and a second region A22 in which the electrode pad 25 is exposed. The second insulating film 27 is an example of an insulating film, and the electrode pad 25 is an example of a conductive film.

Step S1 may include planarizing the surface 10a of the first substrate 10 and the surface 20a of the second substrate 20 by chemical mechanical polishing (CMP). In this case, when the surface 10a of the first substrate 10 and the surface 20a of the second substrate 20 are bonded to each other in step S3, it is possible to suppress the generation of voids due to stepped portions between exposed surfaces of the electrode pads 15 and 25 and exposed surfaces of the second insulating films 17 and 27. Step S1 may include cleaning the surfaces 10a and 20a with a cleaning solution after planarizing the surfaces 10a and 20a.

In step S2, as illustrated in FIG. 4, an ionic liquid is applied to the surface 10a of the first substrate 10. As a result, the surface 10a of the first substrate 10 is covered with a liquid film 18 of the ionic liquid, thereby the exposed surface of the electrode pad 15 from being oxidized.

As an example, step S2 may include gelling or solidifying the liquid film 18 applied to the surface 10a of the first substrate 10. In this case, it is possible to prevent the applied ionic liquid from reacting with the material constituting the electrode pad 15 and melting the exposed surface of the electrode pad 15. For example, in a state in which an ionic liquid in a gel or solid state at a first temperature is heated to a second temperature and liquefied, when the ionic liquid is applied to the first substrate 10 kept at the first temperature, the liquid film 18 may be gelled or solidified. The first temperature may be, for example, room temperature. The second temperature is not particularly limited as long as it is a temperature higher than the first temperature and capable of liquefying the ionic liquid.

The ionic liquid may contain, for example, a material that dissolves an oxide film. In this case, by applying the ionic liquid to the surface 10a of the first substrate 10, it is possible to remove an oxide film such as a natural oxide film or the like which may be generated on the exposed surface of the electrode pad 15.

The ionic liquid may contain, for example, an oxo acid structure having 6 or more carbon atoms. When the number of carbon atoms is 6 or more, the ionic liquid exhibits low viscosity at a relatively low temperature. Thus, the ionic liquid may be applied to the first substrate 10 at a relatively low temperature. The number of carbon atoms is preferably 8 or more. In this case, the ionic liquid is easily applied to the first substrate 10 at a low temperature. The oxo acid structure may be, for example, at least one of a cation or an anion. An example of the oxo acid structure is a carboxylate anion having 6 or more carbon atoms. Decanoate anion (C₉H₁₉COO⁻) may be preferably used as the carboxylate anion having 6 or more carbon atoms. When the ionic liquid contains the carboxylate anion having 6 or more carbon atoms, various cations may be used. Examples of the cation may include a phosphate cation and a sulfate cation. Trihexyltetradecylphosphonium decanoate (THTDP-DcO) may be preferably used as the ionic liquid.

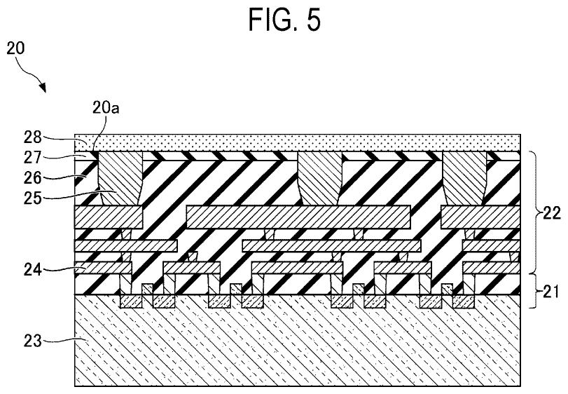

In step S2, as illustrated in FIG. 5, the ionic liquid is applied to the surface 20a of the second substrate 20, similarly to the first substrate 10. Thus, the surface 20a of the second substrate 20 is covered with a liquid film 28 of the ionic liquid, thereby preventing the exposed surface of the electrode pad 25 from being oxidized.

In step S2, for example, the ionic liquid may be applied only to the surface 10a of the first substrate 10, or the ionic liquid may be applied only to the surface 20a of the second substrate 20. In step S2, for example, the ionic liquid may be applied to at least one of the surface 10a of the first substrate 10 or the surface 20a of the second substrate 20.

In step S3, the surface 10a of the first substrate 10 and the surface 20a of the second substrate 20 are bonded to each other via the liquid films 18 and 28.

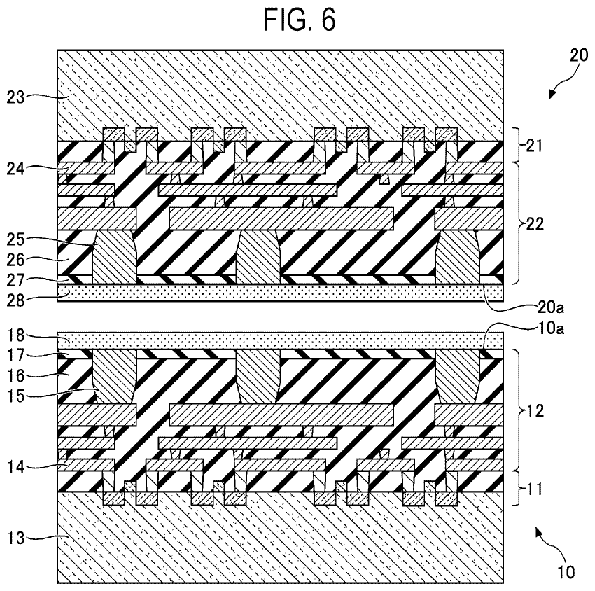

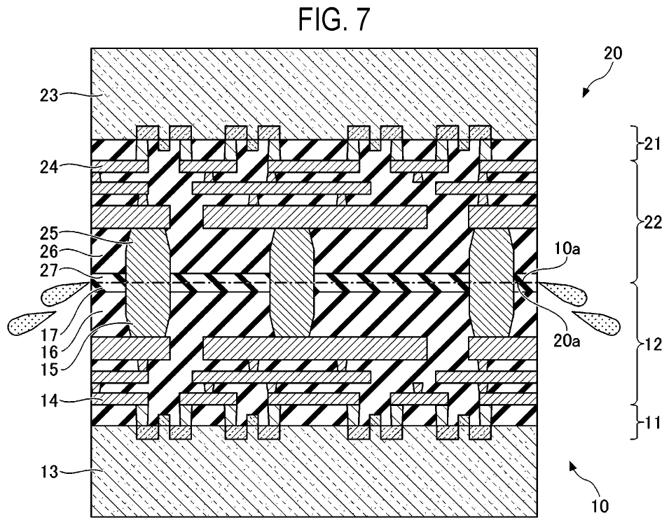

First, as illustrated in FIG. 6, the surface 10a of the first substrate 10 and the surface 20a of the second substrate 20 are held to face each other, and the first substrate 10 and the second substrate 20 are aligned with each other. Such an alignment may include arranging the electrode pad 15 and the electrode pad 25 to face each other. The alignment may include arranging the second insulating film 17 and the second insulating film 27 to face each other.

Subsequently, as illustrated in FIG. 7, the first substrate 10 and the second substrate 20 are heated to a temperature at which the liquid films 18 and 28 are liquefied, the surface 10a of the first substrate 10 and the surface 20a of the second substrate 20 are brought into contact with each other and the first substrate 10 and the second substrate 20 are compressed against each other. As a result, the surface 10a of the first substrate 10 and the surface 20a of the second substrate 20 are brought into close contact with each other. At this time, the ionic liquid obtained from the liquefied liquid films 18 and 28 melts the electrode pads 15 and 25. As a result, metal-metal bonds and metal-carbon-metal bonds are produced through the ionic liquid so that a contact resistance between the electrode pads 15 and 25 is reduced. In addition, when the surface 10a of the first substrate 10 and the surface 20a of the second substrate 20 are bonded to each other, the ionic liquid on the bonding surfaces of the first substrate 10 and the second substrate 20 is extruded and removed. This eliminates a need to remove the liquid films 18 and 28 before bonding the surface 10a of the first substrate 10 and the surface 20a of the second substrate 20 to each other. In addition, for example, when the electrode pads 15 and 25 are made of the same material, galvanic corrosion does not occur even if the electrode pads 15 and 25 come into contact with each other via the ionic liquid. For example, when THTDP-DcO is used as the ionic liquid, the first substrate 10 and the second substrate 20 may be preferably to 230 degrees C. to 240 degrees C. in step S3.

In step S3, for example, the first substrate 10 and the second substrate 20 may be compressed against each other, and subsequently, may be heated to a temperature at which the liquid films 18 and 28 are liquefied.

In step S3, the surface 10a of the first substrate 10 and the surface 20a of the second substrate 20 may be bonded to each other via the liquid films 18 and 28 in a vacuum atmosphere. In this case, the surfaces of the electrode pads 15 and 25 are not exposed to an oxidizing gas or moisture, which makes it possible to suppress oxidation corrosion. Since the ionic liquid is not easily volatilized even in a vacuum atmosphere and a high-temperature environment, the liquid films 18 and 28 do not disappear before the surface 10a of the first substrate 10 and the surface 20a of the second substrate 20 are bonded to each other.

As described above, according to the bonding method of the embodiment, the ionic liquid is applied to the bonding surface of at least one of the first substrate 10 or the second substrate 20, and then the surface 10a of the first substrate 10 and the surface 20a of the second substrate 20 are bonded to each other via the ionic liquid. Thus, the first substrate 10 and the second substrate 20 may be bonded to each other in a state in which the bonding surfaces of the first substrate 10 and the second substrate 20 are protected by the ionic liquid. Therefore, it is possible to suppress the bonding surfaces of the first substrate 10 and the second substrate 20 from being oxidized.

According to the bonding method of the embodiment, when bonding the surface 10a of the first substrate 10 and the surface 20a of the second substrate 20 to each other, the ionic liquid on the bonding surfaces of the first substrate 10 and the second substrate 20 is extruded and removed. This eliminates a need to remove the liquid films 18 and 28 of the ionic liquid before bonding the surface 10a of the first substrate 10 and the surface 20a of the second substrate 20 to each other.

According to the bonding method of the embodiment, the surface 10a of the first substrate 10 and the surface 20a of the second substrate 20 are bonded to each other via the liquid films 18 and 28 in the vacuum atmosphere. Therefore, the surfaces of the electrode pads 15 and 25 are not exposed to an oxidizing gas or moisture, which makes it possible to suppress oxidation corrosion. Since the ionic liquid is not easily volatilized even in the vacuum atmosphere and the high-temperature environment, the liquid films 18 and 28 do not disappear before the surface 10a of the first substrate 10 and the surface 20a of the second substrate 20 are bonded to each other. Therefore, when the first substrate 10 and the second substrate 20 are compressed against each other, degassing hardly occurs from the liquid films 18 and 28. In addition, since the compressed surfaces may be kept in the vacuum state in the high-temperature environment, a very strong adhesion force may be obtained.

According to the bonding method of the embodiment, when bonding the surface 10a of the first substrate 10 and the surface 20a of the second substrate 20 to each other, the ionic liquid dissolves the electrode pads 15 and 25. As a result, metal-metal bonds and metal-carbon-metal bonds are produced through the ionic liquid so that the contact resistance between the electrode pads 15 and 25 is reduced.

As one example of the hybrid bonding in the related art, there is a method of planarizing bonding surfaces of substrates by CMP, and then applying benzotriazole (BTA) to the bonding surfaces to suppress surfaces of conductive films exposed on the bonding surfaces from being oxidized. In this method, the substrates are bonded to each other after removing the BTA. Therefore, the bonding between the conductive films is weak, and voids are generated in the bonding surfaces between the conductive films. This may easily cause connection failure.

As another example of the hybrid bonding in the related art, there is a method of planarizing the bonding surfaces of substrates by CMP, applying a conductive adhesive to the bonding surfaces, and bonding conductive films to each other via the conductive adhesive. In this method, the resistance is likely to increase due to the conductive adhesive. In addition, a leakage current is likely to flow between adjacent conductive films via the conductive adhesive.

In contrast, according to the bonding method of the embodiment, the substrates are bonded to each other via the ionic liquid, so that the conductive films are bonded to each other with a strong adhesion force. This makes it possible to suppress the generation of voids in the bonding surfaces of the conductive films. Further, according to the bonding method of the embodiment, when the substrates are bonded to each other, unnecessary ionic liquid is extruded from the bonding surfaces, and the ionic liquid between the adjacent conductive films is removed. This makes it difficult for a leakage current to flow between the adjacent conductive films.

### [Bonding Apparatus]

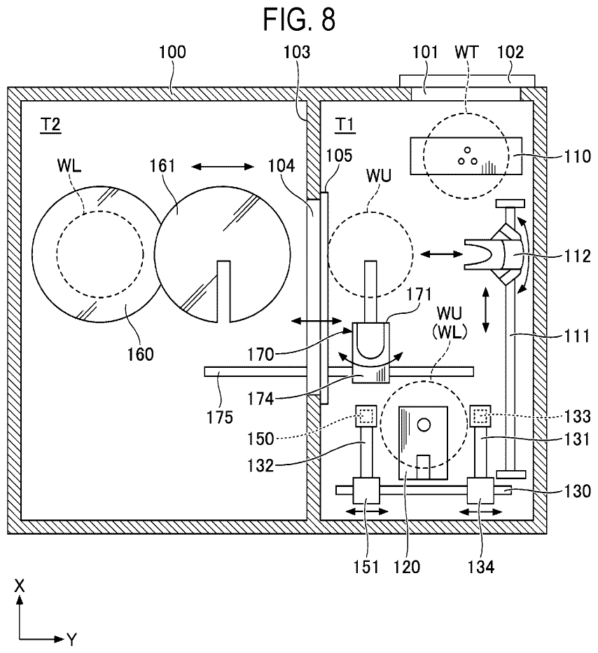

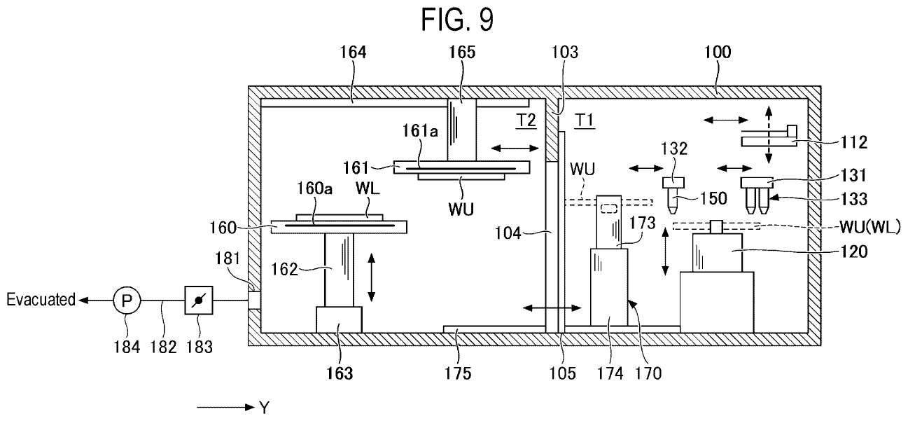

A bonding apparatus for carrying out the bonding method according to the embodiment will be described with reference to FIGS. 8 and 9.

As illustrated in FIG. 8, the bonding apparatus includes a processing container 100 whose interior may be hermetically sealed. A loading/unloading port 101 for transferring an upper substrate WU, a lower substrate WL, and a laminated substrate WT therethrough is provided in a side surface of the processing container 100 in a positive X-direction. The loading/unloading port 101 is opened and closed by an opening/closing shutter 102.

The interior of the processing container 100 is divided into a transfer region T1 and a processing region T2 by an inner wall 103. The loading/unloading port 101 is formed in the side surface of the processing container 100 in the transfer region T1. A loading/unloading port 104 for transferring the upper substrate WU, the lower substrate WL, and the laminated substrate WT therethrough is formed in the inner wall 103. The loading/unloading port 104 is opened and closed by a gate valve 105. The gate valve 105 may be omitted.

A transition 110 is provided on a side of the transfer region T1 in the positive X-direction to temporarily place the upper substrate WU, the lower substrate WL, and the laminated substrate WT thereon. For example, the transition 110 is formed in two stages, and is capable of simultaneously placing two of the upper substrate WU, the lower substrate WL, and the laminated substrate WT thereon.

A substrate transfer body 112, which is movable along a transfer path 111 extending in the X-direction, is provided in the transfer T1. The substrate transfer body 112 is movable in a vertical direction and rotatable around a vertical axis thereof to transfer the upper substrate WU, the lower substrate WL, and the laminated substrate WT inside the transfer region T1 or between the transfer region T1 and the processing region T2.

A position adjuster 120 configured to adjust horizontal orientations of the upper substrate WU and the lower substrate WL is provided on a side of the transfer region T1 in a negative X-direction.

A rail 130 extending along the Y-direction is provided on a side of the position adjuster 120 in the transfer region T1 in the negative X-direction. For example, the rail 130 is provided to extend from the outside of the position adjuster 120 in the negative Y-direction to the outside of the position adjuster 120 in the positive Y-direction. For example, two nozzle arms 131 and 132 are attached to the rail 130.

A nozzle 133 configured to inject the ionic liquid is supported by the nozzle arm 131. The nozzle arm 131 is movable along the rail 130 by a nozzle driver 134. Thus, the nozzle 133 may move from the side of the position adjuster 120 in the positive Y-direction to above the upper substrate WU and the lower substrate WL which are held by the position adjuster 120. The nozzle arm 131 is movable up and down by the nozzle driver 134, and is capable of adjusting a height of the nozzle 133. A supply pipe (not illustrated) through which the ionic liquid is supplied to the nozzle 133 is connected to the nozzle 133. A heater configured to heat the ionic liquid flowing through the supply pipe is provided in the supply pipe.

The nozzle arm 132 supports a nozzle 150 configured to inject the ionic liquid. The nozzle arm 132 is movable along the rail 130 by a nozzle driver 151. Thus, the nozzle 150 may move from the side of the position adjuster 120 in the negative Y-direction to above the upper substrate WU and the lower substrate WL which are held by the position adjuster 120. The nozzle arm 132 is movable up and down by the nozzle driver 151, and is capable of adjusting a height of the nozzle 150. A supply pipe (not illustrated) through which the ionic liquid is supplied to the nozzle 150 is connected to the nozzle 150. A heater configured to heat the ionic liquid flowing through the supply pipe is provided in the supply pipe. Only one of the nozzle 133 and the nozzle 150 may be provided.

A lower chuck 160 for holding the lower substrate WL placed on an upper surface thereof, and an upper chuck 161 for attracting/holding the upper substrate WU placed on a lower surface thereof are provided in the processing region T2. The lower chuck 160 and the upper chuck 161 are accommodated in the processing region T2. The upper chuck 161 is provided above the lower chuck 160. The upper chuck 161 may be arranged to face the lower chuck 160. That is, the lower substrate WL held by the lower chuck 160 and the upper substrate WU held by the upper chuck 161 may be arranged to face each other.

An electrode for electrostatic attraction (not illustrated) electrically connected to a DC power supply (not illustrated) or a suction pipe (not illustrated) in communication with a vacuum pump (not illustrated) is provided inside the lower chuck 160. The lower substrate WL is attracted to and held on the upper surface of the lower chuck 160 by virtue of an electrostatic force such as a Coulomb force or the like generated in the electrode for electrostatic attraction, or by suction from the suction pipe.

A heater 160a is provided inside the lower chuck 160. The heater 160a heats the lower substrate WL attracted to/held by the lower chuck 160.

A chuck driver 163 is provided below the lower chuck 160 via a shaft 162. The chuck driver 163 is configured to raise and lower the lower chuck 160. The chuck driver 163 may be configured to move the lower chuck 160 in the horizontal direction. The chuck driver 163 may be configured to rotate the lower chuck 160 around a vertical axis.

An electrode for electrostatic attraction (not illustrated) electrically connected to a DC power supply (not illustrated) or a suction pipe (not illustrated) in communication with a vacuum pump (not illustrated) is provided inside the upper chuck 161. The upper substrate WU is attracted to and held by the lower surface of the upper chuck 161 by virtue of an electrostatic force such as a Coulomb force or the like generated in the electrode for electrostatic attraction, or by suction from the suction pipe.

A heater 161a is provided inside the upper chuck 161. The heater 161a heats the upper substrate WU attracted to/held by the upper chuck 161.

A rail 164 extending along the Y-direction is provided above the upper chuck 161. The upper chuck 161 may be moved along the rail 164 by a chuck driver 165. The chuck driver 165 is configured to raise and lower the upper chuck 161. The chuck driver 165 may be configured to rotate the upper chuck 161 around a vertical axis.

An inversion mechanism 170, which moves between the transfer region T1 and the processing region T2, is provided in the transfer region T1 to invert the front and back surfaces of the upper substrate WU. The inversion mechanism 170 includes a holding arm 171 for holding the upper substrate WU. A suction pad (not illustrated) for suctioning and holding the upper substrate WU horizontally is provided on the holding arm 171. The holding arm 171 is supported by a driver 173. The driver 173 is configured to rotate the holding arm 171 around a horizontal axis and to extend and contract the holding arm 171 in the horizontal direction. A driver 174 is provided below the driver 173. The driver 174 is configured to rotate the driver 173 around a vertical axis and to raise and lower the driver 173 in the vertical direction. The driver 174 is attached to a rail 175 that extends in the Y-direction. The rail 175 extends from the processing region T2 to the transfer region T1. The inversion mechanism 170 is movable between the position adjuster 120 and the upper chuck 161 along the rail 175 by the driver 174. The configuration of the inversion mechanism 170 is not limited thereto, and may have any configuration as long as it may invert the front and back surfaces of the upper substrate WU. The inversion mechanism 170 may be provided in, for example, the processing region T2. In addition, the inversion mechanism may be provided in the substrate transfer body 112, and another transfer mechanism may be provided at the position of the inversion mechanism 170.

An exhaust port 181 is provided in a side surface of the processing container 100 in the processing region T2. An exhaust passage 182 is connected to the exhaust port 181. A pressure regulation valve 183 and a vacuum pump 184 are sequentially provided in the exhaust passage 182 to exhaust the processing region T2.

### [Operation of Bonding Apparatus]

An operation of the bonding apparatus when bonding the upper substrate WU and the lower substrate WL to each other will be described. The lower substrate WL corresponds to the first substrate 10, and the upper substrate WU corresponds to the second substrate 20.

First, the upper substrate WU is transferred to the bonding apparatus. The upper substrate WU is transferred to the position adjuster 120 by the substrate transfer body 112 via the transition 110. Then, the nozzle 133 is moved to above the central portion of the upper substrate WU by the nozzle arm 131. Then, while rotating the upper substrate WU, an ionic liquid is supplied from the nozzle 133 to the front surface of the upper substrate WU. The supplied ionic liquid is diffused on the front surface of the upper substrate WU by virtue of a centrifugal force, and is applied to the front surface of the upper substrate WU (step S2 in FIG. 1). Then, a horizontal orientation of the upper substrate WU is adjusted by the position adjuster 120.

Subsequently, the upper substrate WU is transferred from the position adjuster 120 to the holding arm 171 of the inversion mechanism 170. Then, in the transfer region T1, the holding arm 171 is inverted to invert the front and back surfaces of the upper substrate WU. That is, the front surface of the upper substrate WU faces downward. Thereafter, the inversion mechanism 170 is moved toward the upper chuck 161, and the upper substrate WU is delivered from the inversion mechanism 170 to the upper chuck 161. The back surface of the upper substrate WU is attracted to/held by the upper chuck 161. Then, the upper chuck 161 is moved by the chuck driver 165 to a position above the lower chuck 160 to face the lower chuck 160. Thereafter, the upper substrate WU waits at the upper chuck 161 until the lower substrate WL (to be described later) is transferred to the bonding apparatus. The front and back surfaces of the upper substrate WU may be inverted while the inversion mechanism 170 is moving.

Subsequently, the lower substrate WL is loaded into the bonding apparatus. The lower substrate WL is transferred to the position adjuster 120 by the substrate transfer body 112 via the transition 110. Then, the nozzle 133 is moved to above the central portion of the lower substrate WL by the nozzle arm 131. Thereafter, while the lower substrate WL is rotating, an ionic liquid is supplied from the nozzle 133 to the front surface of the lower substrate WL. The supplied ionic liquid is diffused on the front surface of the lower substrate WL by virtue of a centrifugal force, and is applied to the front surface of the lower substrate WL (step S2 in FIG. 1). Then, a horizontal orientation of the lower substrate WL is adjusted by the position adjuster 120.

Subsequently, the lower substrate WL is transferred to the lower chuck 160 by the substrate transfer body 112 and is attracted to/held by the lower chuck 160. At this time, the back surface of the lower substrate WL is held by the lower chuck 160 so that the front surface of the lower substrate WL faces upward. A groove (not illustrated) in conformity to a shape of the substrate transfer body 112 may be formed in the upper surface of the lower chuck 160 to prevent interference between the substrate transfer body 112 and the lower chuck 160 when the lower substrate WL is delivered.

Subsequently, the loading/unloading port 104 is closed by the gate valve 105, and the processing region T2 is exhausted and depressurized by the vacuum pump 184.

Thereafter, the horizontal positions of the lower substrate WL held by the lower chuck 160 and the upper substrate WU held by the upper chuck 161 are adjusted. Specifically, first, images of the surfaces of the lower substrate WL and the upper substrate WU are captured using, for example, a CCD camera. Based on the captured images, the horizontal position of the upper substrate WU is adjusted by the upper chuck 161 so that a predetermined reference point (not illustrated) on the front surface of the lower substrate WL coincides with a predetermined reference point (not illustrated) on the front surface of the upper substrate WU. In a case in which the lower chuck 160 is movable in the horizontal direction by the chuck driver 163, the horizontal position of the lower substrate WL may be adjusted by the lower chuck 160. Alternatively, relative horizontal positions of the lower substrate WL and the upper substrate WU may be adjusted by both the lower chuck 160 and the upper chuck 161.

Subsequently, the lower chuck 160 is raised by the chuck driver 163, and the front surface of the lower substrate WL held by the lower chuck 160 and the front surface of the upper substrate WU held by the upper chuck 161 are brought into contact with each other and are compressed against each other. The lower substrate WL is heated by the heater 160a, and the upper substrate WU is heated by the heater 161a. As a result, the upper substrate WU and the lower substrate WL are bonded to each other via the ionic liquid so that the laminated substrate WT is formed (step S3 in FIG. 1).

The embodiments disclosed herein are exemplary in all respects and are not restrictive. The above-described embodiments may be omitted, replaced or modified in various forms without departing from the scope and spirit of the appended claims.

This application claims priority based on Japanese Patent Application No. 2022-112651 filed with the Japan Patent Office on Jul. 13, 2022, and the entire disclosure of Japanese Patent Application No. 2022-112651 is incorporated herein in its entirety by reference.

According to the present disclosure in some embodiments, it is possible to suppress surfaces of substrates bonded to each other from being oxidized.

While certain embodiments have been described, these embodiments have been presented by way of example only, and are not intended to limit the scope of the disclosures. Indeed, the embodiments described herein may be embodied in a variety of other forms. Further, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A bonding method, comprising:
a first operation of preparing a first substrate having a first surface and a second substrate having a second surface, each of the first surface and the second surface having a first region in which an insulating film is exposed and a second region in which a conductive film is exposed;
a second operation of applying an ionic liquid to at least one of the first surface of the first substrate or the second surface of the second substrate; and
a third operation of bonding the first surface of the first substrate and the second surface of the second substrate with the ionic liquid.

2. The bonding method of claim 1, wherein the first operation includes processing the first surface of the first substrate and the second surface of the second substrate by chemical mechanical polishing.

3. The bonding method of claim 1, wherein the second operation includes applying the ionic liquid to the first surface of the second substrate and the second surface of the second substrate.

4. The bonding method of claim 1, wherein the third operation includes compressing the first substrate and the second substrate against each other, and heating the first substrate and the second substrate.

5. The bonding method of claim 4, wherein the second operation includes gelling the ionic liquid applied to the at least one of the first surface of the first substrate or the second surface of the second substrate, and
the heating includes liquefying the ionic liquid gelled in the second operation.

6. The bonding method of claim 1, wherein the third operation is performed in a vacuum atmosphere.

7. The bonding method of claim 1, wherein the conductive film exposed on the first surface of the first substrate and the conductive film exposed on the second surface of the second substrate are made of a same material.

8. The bonding method of claim 1, wherein the ionic liquid is THTDP-DcO.

9. A bonding apparatus, comprising:
an application mechanism configured to apply an ionic liquid to at least one of a first surface of a first substrate or a second surface of a second substrate, each of the first surface and the second surface having a first region in which an insulating film is exposed and a second region in which a conductive film is exposed;
a first holder and a second holder configured to hold the first surface of the second substrate and the second surface of the second substrate so as to face each other; and
a driver configured to bring the second substrate and the second substrate into close contact with each other by allowing the first holder and the second holder to approach each other relatively.

10. The bonding apparatus of claim 9, further comprising:
a heater configured to heat the first substrate and the second substrate held by the first holder and the second holder, respectively.

11. The bonding apparatus of claim 9, further comprising:
a processing container in which the first holder and the second holder are accommodated; and
a vacuum pump configured to exhaust an interior of the processing container.

12. The bonding apparatus of claim 9, wherein the conductive film exposed on the first surface of the second substrate and the conductive film exposed on the second surface of the second substrate are made of a same material.

13. The bonding apparatus of claim 9, wherein the ionic liquid is THTDP-DcO.
